(19) United States
(12) Patent Application Publication
(10) Pub. No.: US 2025/0147411 A1
(43) Pub. Date: May 8, 2025

(54) METHOD FOR OPTIMIZING PHOTOMASK

(71) Applicant: TAIWAN SEMICONDUCTOR MANUFACTURING COMPANY, LTD., Hsinchu (TW)

(72) Inventors: Yen-Tung HU, Hsinchu County (TW); Danping PENG, Fremont, CA (US)

(73) Assignee: TAIWAN SEMICONDUCTOR MANUFACTURING COMPANY, LTD., Hsinchu (TW)

(21) Appl. No.: 18/501,615

(22) Filed: Nov. 3, 2023

(51) Int. Cl. G03F 1/82

(52) U.S. Cl. CPC G03F 1/82

(57) ABSTRACT

A method includes receiving a layout; performing an optimization process to the layout to generate an optimized layout, wherein the optimization process comprising simulating a mask image of a photomask based on the layout; simulating an aerial image projected on a photoresist layer based on the mask image; simulating a resist image of the photoresist layer based on the aerial image; simulating an etch image of a layer underneath the photoresist layer based on the resist image; and performing an inverse lithographic technology (ILT) process to generate the optimized layout, wherein the ILT process is performed based on the mask image, the aerial image, the resist image, and the etch image; and fabricating a photomask based on the optimized layout.

### BACKGROUND

During an integrated circuit (IC) design, a number of patterns of the IC, for different steps of IC processing, are generated on a substrate. The patterns include geometric shapes corresponding to structures to be fabricated on the substrate. The geometric shapes may be projected from a photo mask onto a photo resist layer on the substrate. The photo resist layer is developed to produce the patterns on the photo resist layer. Therefore, it is desirable to determine that the projection and development of the layout pattern produces the desired geometric shapes of the photo mask.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a simplified block diagram of an integrated circuit (IC) manufacturing system and an IC manufacturing flow associated with the IC manufacturing system in accordance with some embodiments of the present disclosure.

FIGS. 2A and 2B illustrate a schematic diagram of an exposure device of a lithography system in accordance with some embodiments of the present disclosure.

FIG. 3 illustrates a block diagram of patterning a layer over a substrate in accordance with some embodiments of the present disclosure.

FIG. 4 illustrates a block diagram of patterning a layer over a substrate in accordance with some embodiments of the present disclosure.

FIG. 5 illustrates a block diagram of a mask optimization module in accordance with some embodiments of the present disclosure.

FIG. 6 illustrates an exemplary training system for training a resist model in accordance with some embodiments of the disclosure.

FIG. 7 illustrates an exemplary training system for training a resist model in accordance with some embodiments of the disclosure.

FIG. 8 illustrates a block diagram of patterning a layer over a substrate in accordance with some embodiments of the present disclosure.

FIG. 9 illustrates schematic views of optimization processes in accordance with some embodiments of the present disclosure.

FIGS. 10A to 10D illustrate patterns at different stages patterning a layer over a substrate in accordance with some embodiments of the present disclosure.

FIG. 11 illustrates an apparatus for manufacturing a lithographic mask for a semiconductor circuit in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

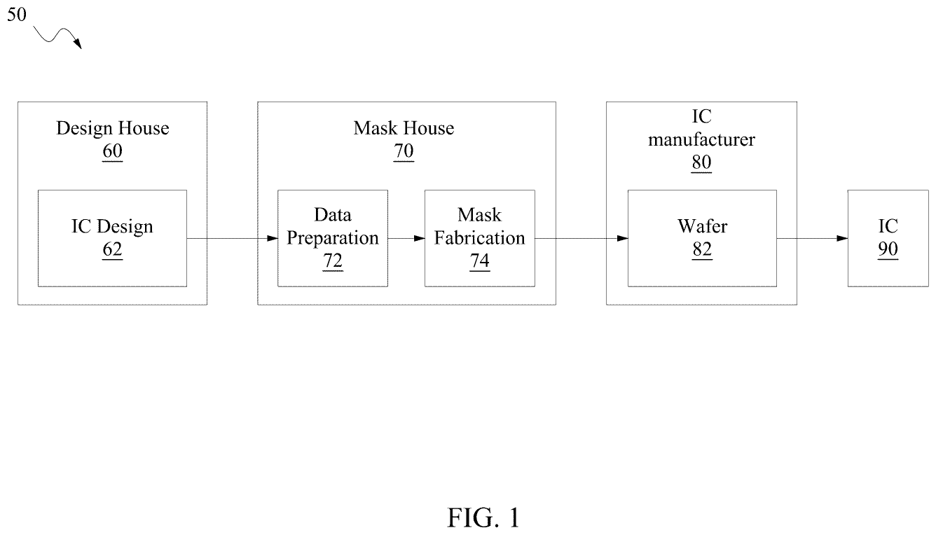

FIG. 1 is a simplified block diagram of an embodiment of an integrated circuit (IC) manufacturing system 50 and an IC manufacturing flow associated with the IC manufacturing system. The IC manufacturing system 50 includes a plurality of entities, such as a design house 60 (or design team), a mask house 70 (or mask team), and an IC manufacturer 80 (or fab), that interact with one another in the design, development, and manufacturing cycles and/or services related to manufacturing an integrated circuit (IC) device 90. The plurality of entities are connected by a communications network, which may be a single network or a variety of different networks, such as a private intranet and/or the Internet, and may include wired and/or wireless communication channels. Each entity may interact with other entities and may provide services to and/or receive services from the other entities. One or more of the design house 60, the mask house 70, and the IC manufacturer 80 may be owned by a single larger company, and may even coexist in a common facility and use common resources.

The design house 60 generates an IC design layout 62. The IC design layout 62 includes various geometrical patterns designed for an IC product, based on a specification of the IC product to be manufactured. The geometrical patterns correspond to patterns of metal, oxide, or semiconductor layers that make up the various components of the IC device 90 to be fabricated. The various layers combine to form various IC features. For example, a portion of the IC design layout 62 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 60 implements a proper design procedure to form the IC design layout 62. The design procedure may include logic design, physical design, and/or place and route. The IC design layout 62 is presented in one or more data files having information of the geometrical patterns. For example, the IC design layout 62 can be expressed in a GDSII file format or DFII file format.

The mask house 70 uses the IC design layout 62 to manufacture one or more masks to be used for fabricating the various layers of the IC device 90 according to the IC design layout 62. The mask house 70 performs data preparation 72, where the IC design layout 62 is translated into a form that can be physically written by a mask writer, and mask fabrication 144, where the design layout prepared by the data preparation 72 is modified to comply with a particular mask writer and/or mask manufacturer and is then fabricated. In the present embodiment, data preparation 72 and mask fabrication 74 are illustrated as separate element, however, data preparation 72 and mask fabrication 74 can be collectively referred to as mask data preparation.

After data preparation 72 and during mask fabrication 74, a mask or a group of masks are fabricated based on the modified IC design layout. For example, an electron-beam (e-beam) or a mechanism of multiple e-beams is used to form a pattern on a mask (photomask or reticle) based on the modified IC design layout. The mask can be formed in various technologies. In an embodiment, a mask pattern includes opaque regions and transparent regions. A radiation beam, such as an ultraviolet (UV) beam, used to expose the image sensitive material layer (e.g., photoresist) coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM as known in the art. In an embodiment, the mask is an extreme ultraviolet (EUV) mask which is a reflective mask in that some portions of its top surface reflect radiation projected thereon in forming an aerial image of IC patterns to be printed on a target, such as a wafer. The EUV mask may incorporate resolution enhancement techniques such as phase-shifting mask (PSM) and/or optical proximity correction (OPC).

After a mask is formed, mask fabrication 74 may include operations to ensure quality of the mask and to gather information for enhancing the mask fabrication process. For example, mask fabrication 74 may inspect the mask for imperfections based on the modified IC design layout and may repair the mask if the imperfections exceed certain limitations. In the present embodiment, mask fabrication 74 utilizes the assistant data produced by data preparation 72 for such tasks. This aspect will be discussed in greater detail in a later section of the present disclosure.

The IC manufacturer 80, such as a semiconductor foundry, uses the mask (or masks) fabricated by the mask house 70 to fabricate the IC device 90. The IC manufacturer 80 is an IC fabrication business that can include a myriad of manufacturing facilities for the fabrication of a variety of different IC products. For example, there may be a manufacturing facility for the front end fabrication of a plurality of IC products (i.e., front-end-of-line (FEOL) fabrication), while a second manufacturing facility may provide the back end fabrication for the interconnection and packaging of the IC products (i.e., back-end-of-line (BEOL) fabrication), and a third manufacturing facility may provide other services for the foundry business. In the present embodiment, a semiconductor wafer 82 is fabricated using the mask (or masks) to form the IC device 90. The semiconductor wafer 82 includes a silicon substrate or other proper substrate having material layers formed thereon. Other proper substrate materials include another suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide. The semiconductor wafer may further include various doped regions, dielectric features, and multilevel interconnects (formed at subsequent manufacturing steps). The mask may be used in a variety of processes. For example, the mask may be used in an ion implantation process to form various doped regions in the semiconductor wafer, in an etching process to form various etching regions in the semiconductor wafer, and/or other suitable processes.

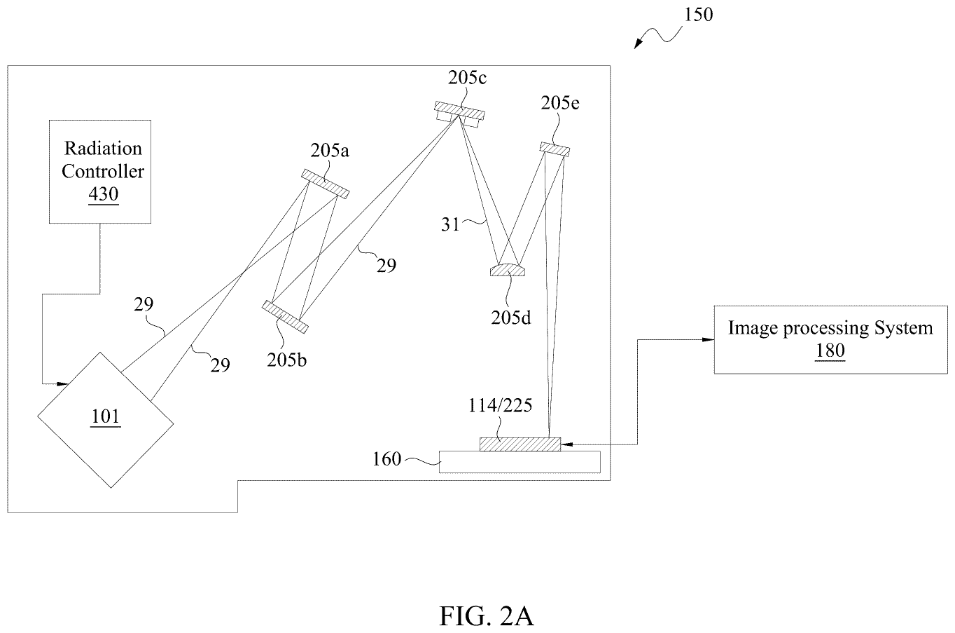

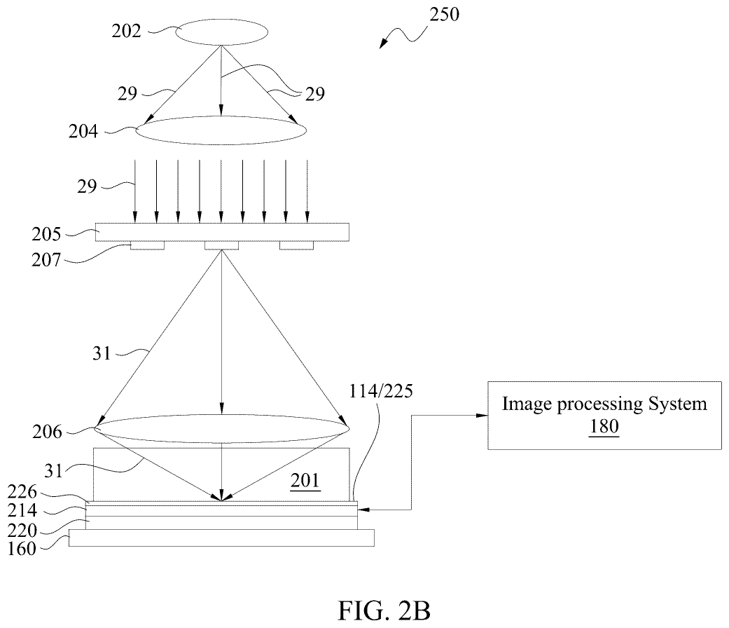

FIGS. 2A and 2B illustrate a schematic diagram of an exposure device of a lithography system in accordance with some embodiments of the present disclosure.

FIG. 2A shows a schematic view of an exposure device 150 for generating a resist pattern on a wafer. The exposure device 150 shows the exposure of the wafer 114 with a patterned beam 31, such as ultraviolet (UV) light or extreme UV (EUV) light. The exposure device 150 may include a wafer movement device, e.g., a stage 160, a stepper, a scanner, a step and scan system, a direct write system, a device using a contact and/or proximity mask, etc., provided with one or more optics 205a, 205b, for example, to illuminate a patterning optic, such as a photomask, e.g., a photomask 205c with a radiation beam 29, e.g., a UV radiation beam or an EUV radiation beam. The illumination of the patterning optics may produce a reflected patterned beam 31. One or more reduction projection optics 205d and 205e of the optical system are used for projecting the patterned beam 31 onto the wafer 114.

As further shown, the exposure device 150 of FIG. 2A includes a radiation source 101 to generate the radiation beam 29 used to irradiate a resist layer on top of the wafer 114, e.g., a substrate. In some embodiments, because gas molecules absorb EUV light, when the radiation source 101 is an EUV radiation source, the exposure device 150, when operated, is maintained under a vacuum environment to avoid EUV intensity loss. In addition, the exposure device 150 includes a radiation controller 430 to control an intensity of the radiation beam 29. In some embodiments, the radiation controller 430 adjusts the radiation by adjusting a projection time of the lithography operation to pattern the resist layer. In some embodiments, the EUV radiation source 101 has a wavelength between about 10 nm and 100 nm.

In some embodiments, the reflected patterned beam 31 is imaged on an image detector 225 instead of the wafer 114. The image detector 225 is coupled to an image processing system 180 that receives the detected image of the projected layout pattern of the photomask 205c. In some embodiments, the image processing system 180 performs one or more processing operations on the detected image to determine, e.g., calculate contours of the detected image and to generate an image of the projected layout pattern of the photomask 205c. The image processing operations include edge detection, morphological operations, etc.

FIG. 2B shows a schematic view of an exposure device 250 for generating a resist pattern on a wafer and includes a radiation source 202 that generates the radiation beam 29, an illumination optics 204, e.g., a lens, for illuminating a photomask 205 (e.g., a transparent mask) with an opaque absorption layer 207 deposited on the transparent mask to define the layout pattern. FIG. 2B also shows reduction projection optics 206, e.g., a lens, for projecting the patterned beam 31 onto the wafer 114 or the image detector 225. The image detector 225 is connected to the image processing system 180 that generates an image corresponding to the layout pattern of the mask. In some embodiments, the wafer 114 or the image detector 225 is immersed in an immersion material 210, e.g., a liquid, and the patterned beam 31 exiting the photomask 205 is in the immersion material 210 when impinging on the wafer 114 or the image detector 225. In some embodiments, the radiation source 202 is a deep UV (DUV) radiation source and has a wavelength between about 100 nm and 300 nm and the immersion material 210 reduces the wavelength of the patterned beam 31.

As discussed with respect to FIGS. 2A and 2B the image generated by the image processing system 180 has the contours of the projected layout pattern of the mask on top of the wafer 114. As shown, the wafer 114 of FIGS. 2A and 2B may include a substrate 220, a first layer 214 disposed over the substrate 220, and a photoresist layer 226 disposed over the first layer 214. In some embodiments, the first layer 214 may be a dielectric layer, a metal layer, a semiconductor layer, or other suitable materials.

In some embodiments, the projected layout pattern of the mask is imaged on the photoresist layer 226 and the photoresist layer 226 is developed to produce a resist pattern in the photoresist layer 226. Afterwards, the first layer 214 is patterned by using photoresist layer 226 as an etch mask, so as to transfer the resist pattern of the photoresist layer 226 to the first layer 214. After the first layer 214 is patterned, the photoresist layer 226 may be removed.

In some embodiments, the resist pattern in the photoresist layer 226 and/or the pattern of the first layer 214 are imaged by a camera or an image detector and the image of the resist pattern is processed by an image processing system, e.g., the image processing system 180, to generate contours of the resist pattern of the photoresist layer 226 and/or contours of the pattern of the first layer 214.

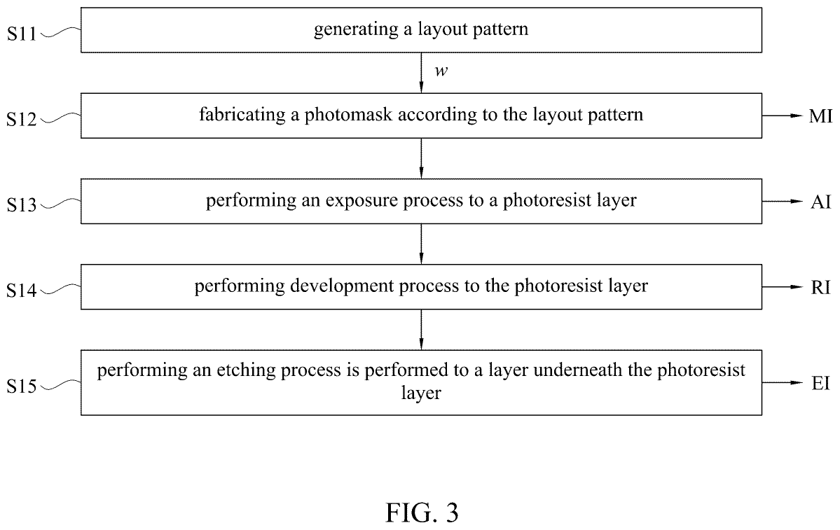

FIG. 3 illustrates a block diagram of patterning a layer over a substrate in accordance with some embodiments of the present disclosure.

The process begins at block S11 where a layout pattern w is generated. For example, the layout pattern w is generated through the design house 60 as discussed in FIG. 1. In some embodiments, the layout pattern w may be a data file, such as a GDS file, having the information of the layout pattern w to be produced on a wafer (e.g., the wafer 114 of FIGS. 2A and 2B). In other embodiments, the layout pattern w may be another data format that is transferred from a GDS file.

The process proceeds to block S12, a photomask is fabricated according to the layout pattern. For example, the photomask may be the photomask 205c of FIG. 2A or the photomask 205 of FIG. 2B, and may be fabricated through the mask house 70 as discussed in FIG. 1. In greater detail, the photomask is fabricated according to the layout pattern w. That is, the mask house 70 of FIG. 1 may receive the layout pattern w from the design house 60, and fabricates the photomask which includes a pattern corresponding to the layout pattern w. After the photomask is fabricated, a mask image MI of the photomask may be imaged by a camera or an image detector. Here, the “mask image” may be an image of a photomask which includes information of the pattern on the photomask.

The process proceeds to block S13, an exposure process is performed to a photoresist layer. For example, the exposure process may be performed using the exposure device 150 of FIG. 2A or the exposure device 250 of FIG. 2B, and may be performed through the IC manufacturer 80 as discussed in FIG. 1. In greater detail, the IC manufacturer 80 may receive the photomask fabricated by the mask house 70, and then dispose the photomask (e.g., the photomask 205c of FIG. 2A or the photomask 205 of FIG. 2B) in an exposure device (e.g., the exposure device 150 of FIG. 2A or the exposure device 250 of FIG. 2B). Afterwards, the exposure process is performed to expose a photoresist layer on a wafer (e.g., the photoresist layer 226 on the wafer 114 as discussed in FIGS. 2A and 2B). For example, the photomask transfer a radiation beam (e.g., the radiation beam 29 of FIGS. 2A and 2B) to a patterned beam (e.g., the patterned beam 31 of FIGS. 2A and 2B), and the patterned beam is projected onto the wafer. During the exposure process of block S13, an aerial image AI is generated. Here, the aerial image may be detected through the image detector 225 of FIGS. 2A and 2B. The aerial image AI may show the light intensity of the patterned beam 31 that is received by the wafer 114 (see FIGS. 2A and 2B). That is, the aerial image AI may be a light distribution diagram that shows the pattern of the patterned beam 31 that is use to expose the photoresist layer on the wafer (e.g., the photoresist layer 226 on the wafer 114 as discussed in FIGS. 2A and 2B). Here, the “aerial image” may be an image which includes information of a pattern that is going to be projected on a wafer.

The process proceeds to block S14, a development process is performed to the photoresist layer. In greater detail, the development process is performed to the exposed photoresist layer, so as to remove unwanted portions of the exposed photoresist layer. The remaining portions of the exposed photoresist layer form a pattern that corresponds to the pattern of the photomask. That is, the photoresist layer is patterned through the exposure process and the development process. After the development process is complete, a resist image AI of the developed photoresist layer is detected. The resist image AI may show the pattern of the photoresist layer after the development process is complete. That is, the resist image AI may also be referred to as after development image (ADI). In some embodiments, the resist image AI can be captured by a camera or an image detector. In some embodiments, the resist image AI can be detected using the image processing system 180 as discussed in FIGS. 2A and 2B. In some embodiments, the resist image AI is a scanning electron microscope (SEM) image, while the disclosure is not limited thereto. Here, the “resist image” may be an image which includes information of a pattern of a patterned photoresist.

The process proceeds to block S15, an etching process is performed to a layer underneath the photoresist layer. In greater detail, the layer is etched by using the patterned photoresist layer as an etch mask, so as to transfer the pattern of the photoresist layer to the layer. That is, the layer is patterned through the patterned photoresist layer and the etching process. After the etching process is complete, an etch image EI of the patterned layer is detected. The etch image EI may show the pattern of the patterned layer after the etching process is complete. That is, the etch image EI may also be referred to as after etch image (AEI). In some embodiments, the etch image EI can be detected by a camera or an image detector. In some embodiments, the etch image EI can be detected using the image processing system 180 as discussed in FIGS. 2A and 2B. In some embodiments, the etch image EI is a scanning electron microscope (SEM) image, while the disclosure is not limited thereto. Here, the “etch image” may be an image which includes information of a pattern of the patterned layer.

As discussed above, the layout pattern w is transferred to the layer through the processes of blocks S11 to S15. Ideally, the contour (pattern) of the etch image EI of the patterned layer will be the same as the layout pattern w. However, due to some process factors, the contour (pattern) of the etch image EI of the patterned layer may be far different from the layout pattern w, and will result in an unsatisfied process result. For example, due to mask manufacturability, the contour (pattern) of the mask image MI may be different from the layout pattern w. Due to image log slope or defocus issue, the contour (pattern) of the aerial image AI may be different from the contour (pattern) of the mask image MI. Due to mask error enhancement error (MEEF) or process variation (PV) band, the contour (pattern) of the resist image (RI) may be different from the contour (pattern) of the aerial image AI. Due to etch placement error (EPE), the contour (pattern) of the etch image EI may be different from the contour (pattern) of the resist image RI. The error occur at each step will result in the final etch image EI having a contour (pattern) that may be far different from the layout pattern w. As a result, the present disclosure provides an optimization method to simulate an etch image EI that is close to the layout pattern w, so as to fabricate a modified photomask. The modified photomask is then fabricated through the process of block S12, and the resulting patterned layer of block S15 may include a contour (pattern) that is close to layout pattern w.

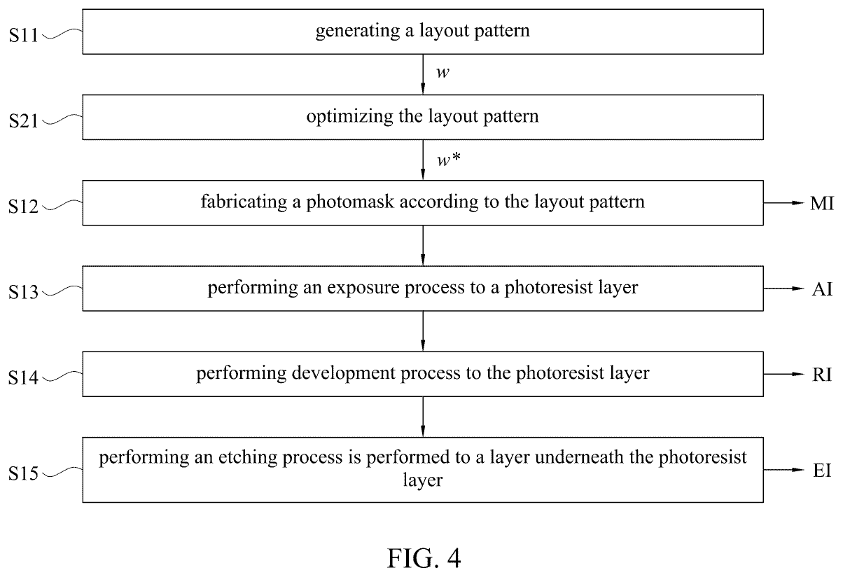

FIG. 4 illustrates a block diagram of patterning a layer over a substrate in accordance with some embodiments of the present disclosure. It is noted that some processes as described in FIG. 4 is similar to those described with respect to FIG. 3, and thus relevant details will not be repeated for brevity.

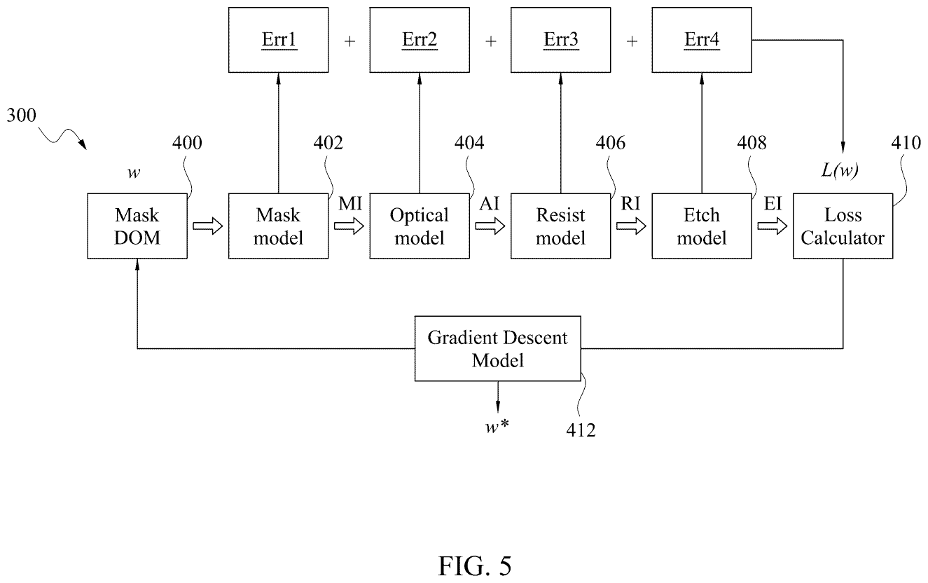

FIG. 4 is different from FIG. 3, in that prior to performing the block S12, the method proceeds to block S21 by optimizing the layout pattern. In some embodiments, the layout pattern w is optimized through a mask optimization module (e.g., the mask optimization module 300 in FIG. 5). As described in more details below with respect to FIG. 5, the mask optimization module performs an inverse lithographic technology (ILT) process in some embodiments. The mask optimization module performs a simulation process to create an optimized layout pattern w*. The optimized layout pattern w* is created as a photomask in block S12. As a result, after the process of block S15 is complete, resulting patterned layer (e.g., etch image EI) of block S15 may include a contour (pattern) that is close to the original layout pattern w.

In some embodiments, the ILT process is applied to the corrected layout pattern of the photomask to remedy the remaining defective areas. In some embodiments, the ILT process is performed as an iterative process. In some embodiments, the iterative process has a number of iterations. In some embodiments, in each iteration, the etch image is simulated (or predicted). When a difference (e.g., loss) between the simulated etch image and the original layout pattern w is minimum or zero, the corresponding optimized layout pattern w* is selected.

FIG. 5 illustrates a block diagram of a mask optimization module in accordance with some embodiments of the present disclosure. In greater detail, FIG. 5 illustrates a mask optimization module 300 that is used to perform the optimizing step in FIG. 4 (e.g., block S21).

The mask optimization module 300 includes a mask dimension on mask (DOM) 400. The mask DOM 400 provides a layout pattern w as an input of the mask optimization module 300.

The mask optimization module 300 further includes a mask model 402. The mask model 402 receives the layout pattern w and simulates (or predicts) a mask image MI based on the layout pattern w. Stated another way, the layout pattern w is used as an input of the mask model 402, and the simulated mask image MI is an output of the mask model 402. In some embodiments, the mask model 402 may apply a predetermined function to the layout pattern w to generate the simulated mask image MI, and thus the simulated mask image MI can be regarded as a function of the layout pattern w. That is, the mask image MI can be expressed as F₁(w). In some embodiments, the mask model 402 may simulates the mask image MI using multiple Gaussian kernels applied to the layout pattern w. In some embodiments, the kernels may describe e-beam process behavior while performing mask making.

The mask optimization module 300 further includes an optical model 404. The optical model 404 receives the mask image MI and simulates (or predicts) an aerial image AI based on the mask image MI. Stated another way, the mask image MI is used as an input of the optical model 404, and the simulated aerial image AI is an output of the optical model 404. In some embodiments, the optical model 404 may apply a predetermined function to the mask image MI to generate the simulated aerial image AI, and thus the simulated aerial image AI can be regarded as a function of the mask image MI. That is, the aerial image AI can be expressed as F₂(MI). In some embodiments, the optical model 404 may simulates the aerial image AI using Hopkins theory.

The mask optimization module 300 further includes a resist model 406. The resist model 406 receives the aerial image AI and simulates (or predicts) a resist image RI based on the aerial image AI. Stated another way, the aerial image AI is used as an input of the resist model 406, and the simulated resist image RI is an output of the resist model 406. In some embodiments, the resist model 406 may be a machine-leaning based module, which is used to generate the simulated resist image RI, and thus the simulated resist image RI can be regarded as a function of the aerial image AI. That is, the resist image RI can be expressed as F₃(AI).

The mask optimization module 300 further includes an etch model 408. The etch model 408 receives the resist image RI and simulates (or predicts) an etch image EI based on the resist image RI. Stated another way, the resist image RI is used as an input of the etch model 408, and the simulated etch image EI is an output of the etch model 408. In some embodiments, the etch model 408 may be a machine-leaning based module, which is used to generate the simulated etch image EI, and thus the simulated etch image EI can be regarded as a function of the resist image RI. That is, the etch image EI can be expressed as F₄(RI).

The mask optimization module 300 further includes a loss calculator 410. The loss calculator 410 calculates a difference between the simulated etch image EI and the layout pattern w, and the difference can be regarded as a “loss”. Stated another way, the simulated etch image EI is used as an input of the loss calculator 410, and the calculated loss is an output of the loss calculator 410. That is, the loss function can be expressed as L(EI). However, because the simulated etch image EI is simulated, through the models 402 to 408, by using the layout pattern w as an initial input, the loss function can also be expressed as L(w). In some embodiments, the difference between the simulated etch image EI and the layout pattern w can also be regarded as etch placement error (EPE).

In some embodiments, each of the mask model 402, the optical model 404, the resist model 406, and the etch model 408 may include an error model configured to calculate error at the current stage. The mask model 402 has an error model Err1 configured to generate an error between the mask image MI and the layout pattern w. Due to mask manufacturability, the contour (pattern) of the mask image MI may be different from the layout pattern w. The optical model 404 has an error model Err2 configured to generate an error between the aerial image AI and the mask image MI. Due to image log slope (ILS) or defocus issue, the contour (pattern) of the aerial image AI may be different from the contour (pattern) of the mask image MI. The resist model 406 has an error model Err3 configured to generate an error between the resist image RI and the aerial image AI. Due to mask error enhancement error (MEEF) or process variation (PV) band, the contour (pattern) of the resist image (RI) may be different from the contour (pattern) of the aerial image AI. The etch model 408 has an error model Err4 configured to generate an error between the etch image EI and the resist image RI. Due to etch placement error (EPE), the contour (pattern) of the etch image EI may be different from the contour (pattern) of the resist image RI. The errors generated by the error models Err1 to Err4 may result in the loss as calculated by the loss calculator 410.

The mask optimization module 300 further includes a gradient descent model 412. The gradient descent model 412 is configured to perform gradient descent, which is a first-order iterative optimization algorithm for finding a minimum value of a differentiable function. In greater detail, the gradient descent model 412 configured to calculate a minimum value of the loss function L(w). For example, the gradient descent can be expressed as:

$${{w}^{1} ← {w}^{0} - η \frac{dL}{dw} \vert}_{w = {w}^{0}} \\ {w}^{*} = arg min L ( w )$$

Here, η is learning rate, L is the loss function L(w), w is the variable, and n*dL/dw is the “gradient”. In this case, w is the layout pattern, and loss function L(w) is the difference between the simulated etch image EI and the original layout pattern w. In the beginning of the gradient descent, w⁰ is an initial input generated by the mask DOM 400, in which w⁰ is the same as the original layout pattern w. w⁰ is used as an input of the mask model 402, and the corresponding loss L(w⁰) can be obtained through the mask model 402, the optical model 404, the resist model 406, the etch model 408, and the loss calculator 410. Then, the loss L(w⁰) is used as the input of the gradient descent model 412, and the gradient descent model 412 calculates w¹ based on the formula as described above. Afterwards, in the first iteration of the gradient descent, w¹ is again used as an input of the mask model 402, and the corresponding loss L(w¹) can be obtained through the mask model 402, the optical model 404, the resist model 406, the etch model 408, and the loss calculator 410. The gradient descent model 412 performs the iterative process until the minimum value of the loss L(w) is obtained, and the corresponding layout pattern w* is output as a result of the gradient descent model 412.

If the iterative process includes several iterations, the iterative process can be expressed below:

$${{{{w}^{1} ← {w}^{0} - η \frac{dL}{dw} \vert}_{w = {w}^{0}} \\ {w}^{2} ← {w}^{1} - η \frac{dL}{dw} \vert}_{w = {w}^{1}} \\ ⋮ \\ {w}^{*} ← {w}^{* - 1} - η \frac{dL}{dw} \vert}_{w = {w}^{* - 1}} \\ {w}^{*} = arg min L ( w )$$

In the method as discussed above, it is important to get the “gradient” to solve optimization problem. Using chain rule, it is possible to simply divide the gradient into several terms. Typical chain rule is expressed below:

$$\frac{{dmodel}_{out}}{{dmodel}_{in}} = \frac{{dmodel}_{out}}{{dOP}_{n}} * \frac{{dOP}_{n}}{{dOP}_{n - 1}} * … * \frac{{dOP}_{0}}{{dmodel}_{in}}$$

As shown above, using chain rule again can split each term above into derivative components. OPn is the operators used in the models to simulate corresponding process behaviors.

Based on the concept of chain rule, it is possible to change the gradient into following form:

$$\frac{dL}{dw} = \frac{dL}{dEI} * \frac{dEI}{dRI} * \frac{dRI}{dAI} * \frac{dAI}{dMI} * \frac{dMI}{dw}$$

Thus, the gradient descent can be expressed as:

$${{w}^{1} ← {w}^{0} - η \frac{dL}{dEI} * \frac{dEI}{dRI} * \frac{dRI}{dAI} * \frac{dAI}{dMI} * \frac{dMI}{dw} \vert}_{EI = {EI}^{0} , RI = {RI}^{0} , AI = {AI}^{0} , MI = {MI}^{0} , w = {w}^{0}} \\ {w}^{*} = arg min L ( w )$$

Here, L is the loss function L(w), EI is the simulated etch image, RI is the simulated resist image, AI is the simulated aerial image, MI is the simulated mask image. As mentioned above, the loss can also be expressed as L (EI), the simulated etch image EI can be expressed as F₄(RI), the simulated resist image RI can be expressed as F₃(AI), the simulated aerial image can be expressed as F₂(MI), and the simulated mask image MI can be expressed as F₁(w). Accordingly, the gradient descent can be further expressed as:

$${{w}^{1} ← {w}^{0} - η \frac{dL ( EI )}{dEI} * \frac{{dF}_{4} ( RI )}{dRI} * \frac{{dF}_{3} ( RI )}{dAI} * \frac{{dF}_{2} ( MI )}{dMI} * \frac{{dF}_{1} ( w )}{dw} \vert}_{\begin{matrix}EI = {EI}^{0} , RI = {RI}^{0} , \\ AI = {AI}^{0} , MI = {MI}^{0} , \\ w = {w}^{0}\end{matrix}} \\ {w}^{*} = arg min L ( w )$$

As a result, it can be seen that in the mask optimization module 300, each step is taken into account. That is, the mask model 402, the optical model 404, the resist model 406, the etch model 408, and the loss calculator 410 are taken into account during the optimization process. In greater detail, in the beginning of the gradient descent, w⁰ is an initial input generated by the mask DOM 400, in which w⁰ is the same as the original layout pattern w. w⁰ is used as an input of the mask model 402, and the corresponding mask image MI⁰, aerial image AI⁰, resist image RI⁰, etch image EI⁰, and loss L(w⁰) can be obtained through the mask model 402, the optical model 404, the resist model 406, the etch model 408, and the loss calculator 410, respectively. Then, the loss L(w⁰) is used as the input of the gradient descent model 412, and the gradient descent model 412 calculates w¹ based on the formula as described above. Afterwards, in the first iteration of the gradient descent, w¹ is again used as an input of the mask model 402, and the corresponding mask image MI¹, aerial image AI¹, resist image RI1, etch image EI¹, and loss L(w¹) can be obtained, accordingly. The gradient descent model 412 performs the iterative process until the minimum value of the loss L(w) is obtained, and the corresponding layout pattern w*, mask image MI*, aerial image AI*, resist image RI*, etch image EI* is output as a result of the gradient descent model 412.

Once the layout pattern w* that results in the minimum value of the loss L(w) is obtained, it indicates that the corresponding etch image EI* has minimum loss from the original layout pattern w (or w⁰ as described in the gradient decent process). Accordingly, referring back to FIG. 4, in block S12, a photomask may be fabricated based on the optimized mask image MI* (or the optimized layout pattern w*), and the resulting patterned layer (e.g., etch image EI) of block S15 may include a contour (pattern) that is close to the original layout pattern w.

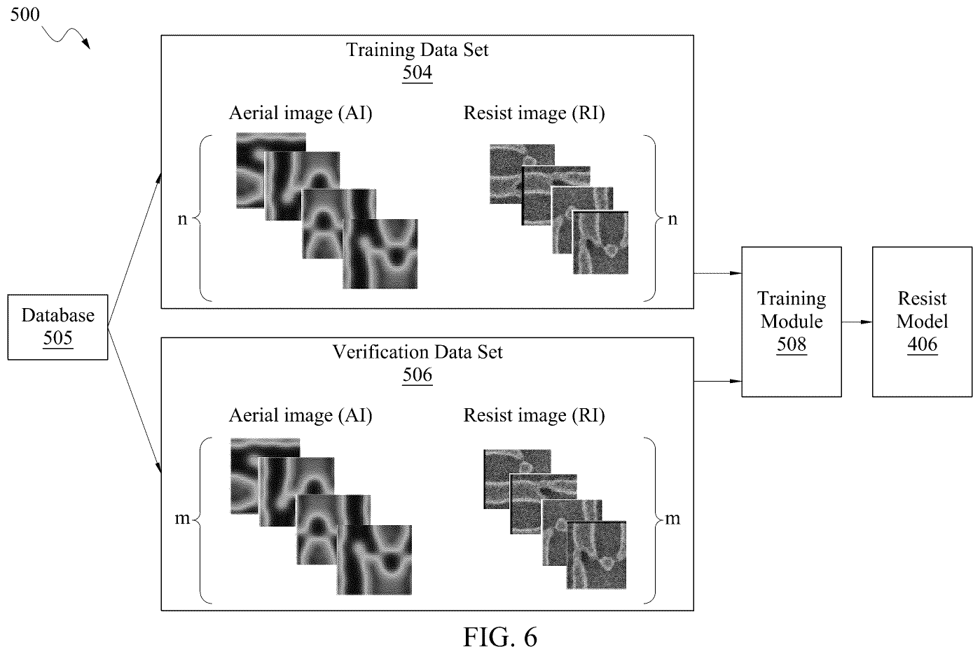

FIG. 6 illustrates an exemplary training system for training a resist model in accordance with some embodiments of the disclosure. As mentioned above with respect to FIG. 5, the resist model 406 may be a machine-leaning (ML) based module. The training system 500 of FIG. 6 may be used to train the resist model 406.

The training system 500 includes a database 505, in which each record of the database 505 includes aerial images AI and resist images RI corresponding to the aerial images AI. Here, the aerial images AI and resist images RI may be experiment data collected through the processes as discussed in blocks S13 and S14 of FIG. 4, respectively. In some embodiments, the records of the database 505 are divided into a training data set 504 and a verification data set 506. For example, the training data set 504 includes n sets of aerial images AI and n sets of the corresponding aerial images AI. On the other hand, the verification data set 506 includes m sets of aerial images AI and m sets of the corresponding aerial images AI. In some embodiments, n is greater than m. In some embodiments, a training module 508 of the training system 500 uses the training data set 904 to train the resist model 406. As noted, the aerial image AI is an input of the resist model 406 and a resist image RI is the output of the resist model 406.

In some embodiments, the training of the resist model 406 includes setting the parameters of the resist model 406 such that each aerial image AI of a record of the database 505 produces the corresponding resist image RI of the same record of the database 505. In some embodiments, the parameters of resist model 406 are the parameters of a neural network, e.g., a deep neural network. In some embodiments, the parameters of the resist model 406 are determined in an iterative procedure. Initially, the parameters are set to initial values, e.g., random values, the outputs of the resist model 406 to each aerial image AI as the inputs are determined, and an error, e.g., sum of the squared differences between the corresponding resist image RI of the database 505 and the outputs of the resist model 406 are determined. Then, the parameters of the resist model 406 are iteratively modified until the error is minimized, e.g., the error becomes less than a threshold.

In some embodiments, after the training module 508 trains the resist model 406 with the training data set 504, the training module 508 verifies the training with a verification data set 506. In some embodiments, the verification data set 506 is separate from the training data set 504 and the training is verified when for each record of the training data set 504 an error, e.g., a squared error, between the resist image RI of a record of the database 505 and the output of the resist model 406 of the corresponding aerial image AI of the same record is below a threshold level. In some embodiments, if the training is not verified, the training data set 504 is increased and the resist model 406 is retrained.

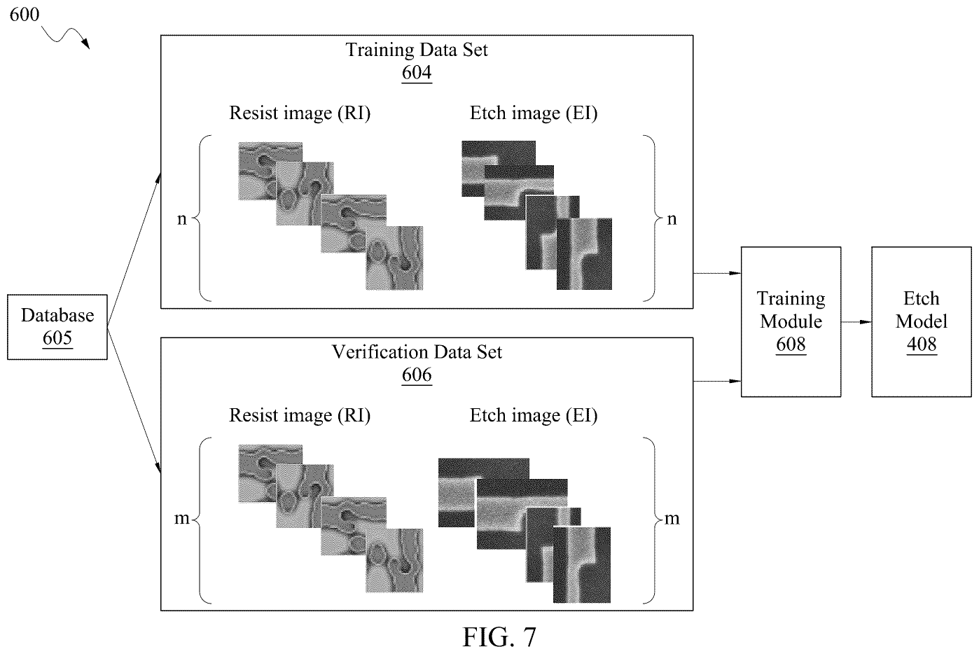

FIG. 7 illustrates an exemplary training system for training a resist model in accordance with some embodiments of the disclosure. As mentioned above with respect to FIG. 5, the etch model 408 may be a machine-leaning (ML) based module. The training system 600 of FIG. 7 may be used to train the etch model 408.

The training system 600 includes a database 605, in which each record of the database 605 includes resist images RI and etch images EI corresponding to the resist images RI. Here, the resist images RI and etch images EI may be experiment data collected through the processes as discussed in blocks S14 and S15 of FIG. 4, respectively. In some embodiments, the records of the database 605 are divided into a training data set 604 and a verification data set 606. For example, the training data set 604 includes n sets of resist images RI and n sets of the corresponding etch images EI. On the other hand, the verification data set 606 includes m sets of resist images RI and m sets of the corresponding etch images EI. In some embodiments, n is greater than m. In some embodiments, a training module 608 of the training system 600 uses the training data set 904 to train the etch model 408. As noted, the resist image RI is an input of the etch model 408 and the etch image EI is an output of the etch model 408.

In some embodiments, the training of the etch model 408 includes setting the parameters of the etch model 408 such that each resist image RI of a record of the database 605 produces the corresponding etch image EI of the same record of the database 605. In some embodiments, the parameters of etch model 408 are the parameters of a neural network, e.g., a deep neural network. In some embodiments, the parameters of the etch model 408 are determined in an iterative procedure. Initially, the parameters are set to initial values, e.g., random values, the outputs of the etch model 408 to each resist image RI as the inputs are determined, and an error, e.g., differences between the corresponding etch image EI of the database 605 and the outputs of the etch model 408 are determined. Then, the parameters of the etch model 408 are iteratively modified until the error is minimized, e.g., the error becomes less than a threshold.

In some embodiments, after the training module 608 trains the etch model 408 with the training data set 604, the training module 608 verifies the training with a verification data set 606. In some embodiments, the verification data set 606 is separate from the training data set 604 and the training is verified when for each record of the training data set 604, an error between the etch image EI of a record of the database 605 and the output of the etch model 408 of the corresponding resist image RI of the same record is below a threshold level. In some embodiments, if the training is not verified, the training data set 604 is increased and the etch model 408 is retrained.

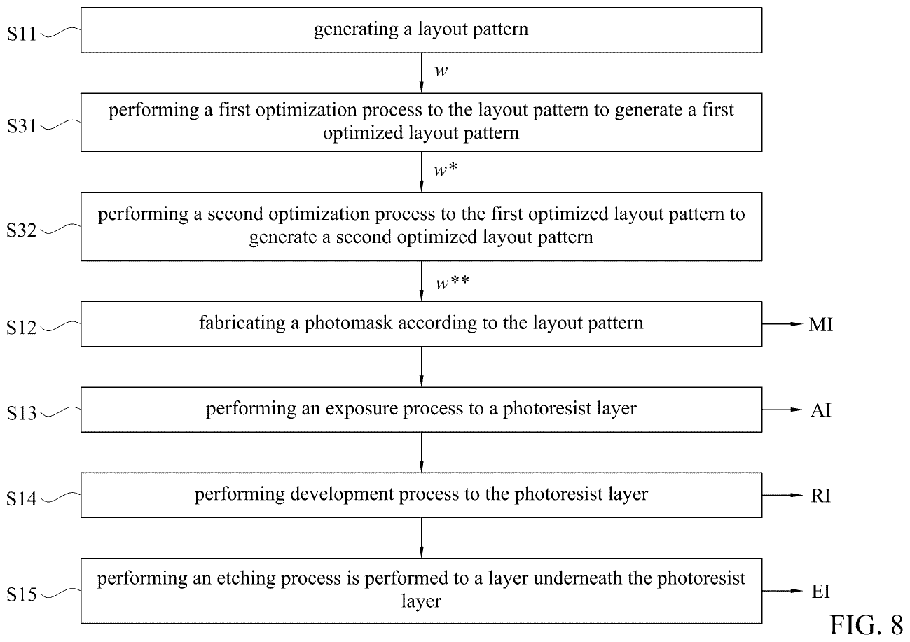

FIG. 8 illustrates a block diagram of patterning a layer over a substrate in accordance with some embodiments of the present disclosure. It is noted that some processes as described in FIG. 8 is similar to those described with respect to FIGS. 3 and 4, and thus relevant details will not be repeated for brevity.

Prior to performing the block S12, the method proceeds to block S31 by performing a first optimization process to the layout pattern to generate a first optimized layout pattern. Here, the first optimization process may be similar to those described in block S21 of FIG. 4 and FIGS. 5 to 7. For example, an original layout pattern w is optimized, so as to generate a first optimized layout pattern w*.

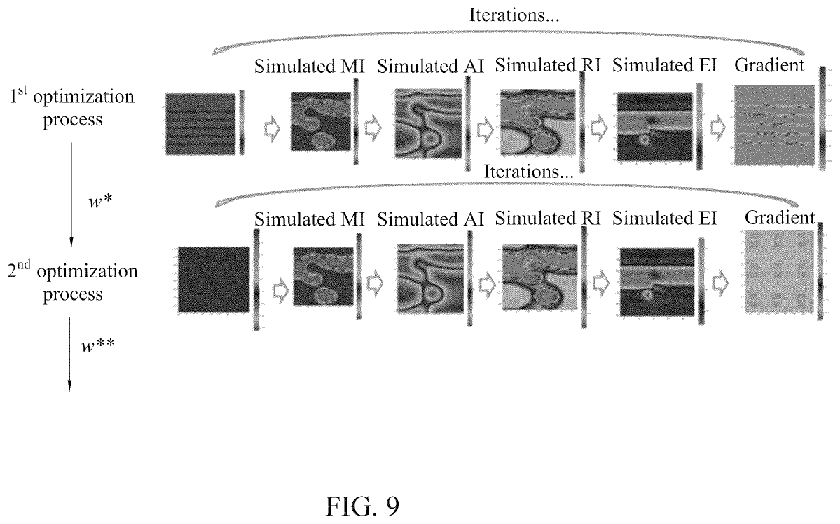

The process proceeds to block S32 by performing a second optimization process to the layout pattern to generate a second optimized layout pattern. In greater detail, the first optimized layout pattern w* is optimized again, for example, using the mask optimization module 300 in FIG. 5. That is, the mask optimization module performs the ILT process again to the first optimized layout pattern w* to obtain a second optimized layout pattern w**. The difference between the first optimization process and the second optimization process are described in FIG. 9.

FIG. 9 illustrates schematic views of optimization processes in accordance with some embodiments of the present disclosure. Show there are the first optimization process and the second optimization process as discussed in blocks S31 and S32 of FIG. 8, respectively.

In the first optimization process, real valued image is used as an initial input of the first optimization process. Although the initial input, such as the original layout pattern w, is not a real valued image. For example, the original layout pattern w may be a GDS file. The GDS file is transferred to a real valued image in advance. Then, the first optimization process uses the real valued image, which includes the information of the original layout pattern w, as an initial input to generate a first optimized layout pattern w*. Here, the real valued image may be a grey-level image, in which each pixel of the image may include a value ranged from 0 to 1.

After the first optimization process is complete, the first optimized layout pattern w* is generated, and the first optimized layout pattern w* is used as an input of the second optimization process. The second optimization process is similar to the first optimization process, in which the second optimization process includes the mask optimization module 300 as discussed in FIG. 5. The difference between first optimization process and the second optimization process is that the initial input (e.g., first optimized layout pattern w*) of the second optimization process is transferred to a level-set image instead of a real valued image. In some embodiments, the level-set image is a binary intensity image. That is, in a level-set image, there is only 1 or 0 in each pixel of the image, and the resulting image may show the contour of the pattern. In some embodiments, the level-set image may be generated through fast-sweep method.

In greater detail, prior to performing the second optimization process, the first optimized layout pattern w* is transferred (e.g., from a real image) to a level-set image, and the level-set image of the first optimized layout pattern w* is used as an input of the second optimization process. The mask optimization module 300 may transfer the input of each iteration to a level-set image. Because the level-set image is in a form that is close to the original layout pattern w, by using the second optimization process it is beneficial to generate a satisfying simulation result (e.g., the second optimized layout pattern w**).

The second optimization process performs the iterative process until the minimum value of the loss L(w) is obtained, and the corresponding layout pattern w**, mask image MI**, aerial image AI**, resist image RI**, etch image EI** are output as a result of the second optimization process.

Once the layout pattern w** that results in the minimum value of the loss L(w) is obtained, it indicates that the corresponding etch image EI** has minimum loss from the original layout pattern w (or w⁰ as described in the gradient decent process). Accordingly, referring back to FIG. 8, in block S12, a photomask may be fabricated based on the optimized mask image MI** (or the optimized layout pattern w**), and the resulting patterned layer (e.g., etch image EI) of block S15 may include a contour (pattern) that is close to the original layout pattern w.

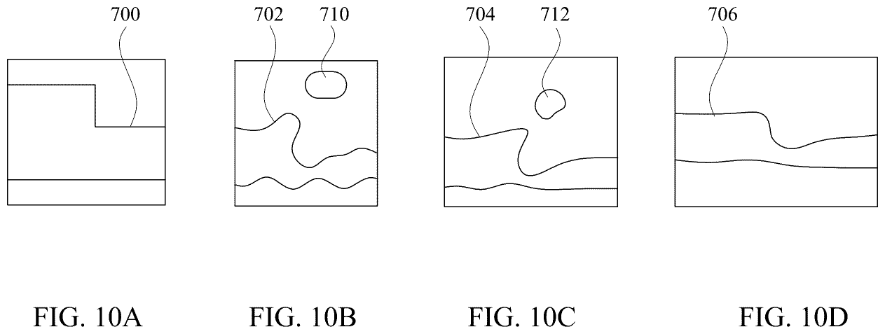

FIGS. 10A to 10D illustrate patterns at different stages patterning a layer over a substrate in accordance with some embodiments of the present disclosure. In FIG. 10A, shown there is an original layout pattern w, in which the original layout pattern w includes a feature 700.

In FIG. 10B, shown there is a mask image MI of a photomask fabricated based on the optimized layout pattern (e.g., w* or w**). Here, the photomask may be the photomask 205c of FIG. 2A or the photomask 205 of FIG. 2B. In greater detail, the pattern of the photomask includes a feature 702 that corresponds to the feature 700 original layout pattern w. However, the pattern of the photomask further includes an island-like assisting feature 710 adjacent to a corner of the feature 702. The assisting feature 710 is not present in the original layout pattern w. The assisting feature 710 is generated through the optimization process as discussed above. It is difficult to place such feature by rules or other traditional methods because its locations will be complicated with different CD and space environments and can only be determined by the models as discussed above (e.g., models 402 to 408).

In FIG. 10C, shown there is a resist image MI of a photoresist layer when the pattern of the photomask of FIG. 10B is imaged on the photoresist layer, for example, through the process of blocks S13 and 14 of FIGS. 4 and 8 as discussed above. Here, the photoresist layer may be the photoresist layer 226 as discussed in FIGS. 2A and 2B. In greater detail, the pattern of the photoresist layer includes a feature 704 that corresponds to the feature 702 of the photomask and the feature 700 of the original layout pattern w. The pattern of the photomask further includes an island-like assisting feature 712 adjacent to a corner of the feature 704, and the island-like assisting feature 712 corresponds to the island-like assisting feature 710 of the photomask of FIG. 10B. Similarly, the assisting feature 712 is not present in the original layout pattern w. The assisting feature 712 is resulted from the assisting feature 710 generated through the optimization process as discussed above.

In FIG. 10D, shown there is an etch image EI of a layer when the pattern of the photoresist layer of FIG. 10C is transferred on the layer, for example, through the process of block S15 of FIGS. 4 and 8 as discussed above. Here, the layer may be the first layer 214 as discussed in FIGS. 2A and 2B. In greater detail, the pattern of the layer includes a feature 706 that corresponds to the feature 704 of the photoresist layer, the feature 702 of the photomask, and the feature 700 of the original layout pattern w. It is noted that the pattern of the island-like assisting feature 712 in the photoresist layer is not transferred to the patterned layer. A possible reason may be the island-like assisting feature 712 of the photoresist layer may be too small and thus the etching process for etching the underlying layer may still remove the portion of the layer that is vertically below the island-like assisting feature 712. However, the island-like assisting feature 712 of the photoresist layer may act as a buffer layer for lowering the etching rate at this region. In this way, the corner of the feature 706 may not be rounded too much, and the resulting pattern of the feature 706 of the layer may be close to the pattern of the feature 700 of the original layout pattern w.

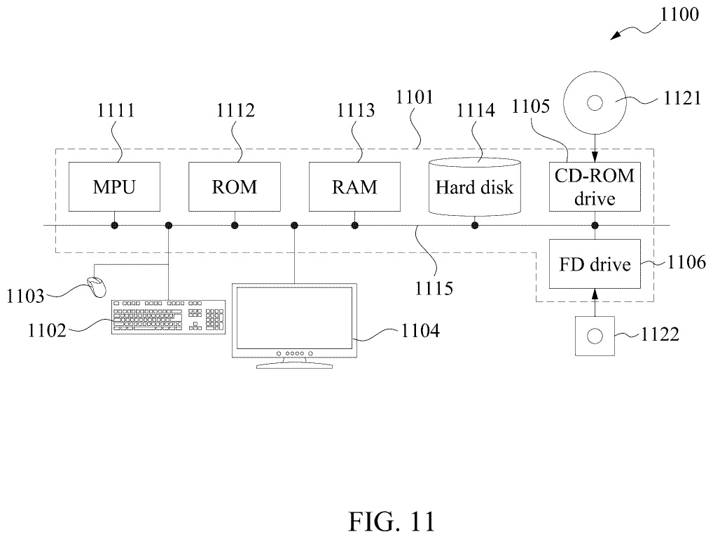

FIG. 11 illustrates an apparatus for manufacturing a lithographic mask for a semiconductor circuit in accordance with some embodiments of the disclosure. FIG. 11 is a schematic view of a computer system that executes the process for manufacturing the lithographic mask according to one or more embodiments as described above. All of or a part of the processes, method and/or operations of the foregoing embodiments can be realized using computer hardware and computer programs executed thereon. The operations include every part of the mask optimization module 300 and the training systems 500 and 600. In FIG. 11, a computer system 1100 is provided with a computer 1101 including an optical disk read only memory (e.g., CD-ROM or DVD-ROM) drive 1105 and a magnetic disk drive 1106, a keyboard 1102, a mouse 1103, and a monitor 1104.

In greater detail, the computer 1101 is provided with, in addition to the optical disk read only memory drive 1105 and the magnetic disk drive 1106, one or more processors, such as a micro processing unit (MPU) 1111, a ROM 1112 in which a program, such as a boot up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

The program for causing the computer system 1100 to execute the process for manufacturing the lithographic mask of a semiconductor device in the foregoing embodiments may be stored in an optical disk 1121 or a magnetic disk 1122, which are inserted into the optical disk read only memory drive 1105 or the magnetic disk drive 1106, and transmitted to the hard disk 1114. Alternatively, the program may be transmitted via a network (not shown) to the computer 1101 and stored in the hard disk 1114. At the time of execution, the program is loaded into the RAM 1113. The program may be loaded from the optical disk 1121 or the magnetic disk 1122, or directly from a network. The program does not necessarily have to include, for example, an operating system (OS) or a third party program to cause the computer 1101 to execute the process for manufacturing the lithographic mask of a semiconductor device in the foregoing embodiments. The program may only include a command portion to call an appropriate function (module) in a controlled mode and obtain desired results.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method to optimize a photomask. The optimization includes performing an inverse lithographic technology (ILT) process by taken mask image, aerial image, resist image, and etch image into account, which will improve the accuracy of the lithography process. Embodiments of the present disclosure also provide a two-step optimization to the layout pattern, in which a first optimization is performed using real image, and a second optimization is performed using level-set image, which will improve the accuracy of the lithography process.

In some embodiments of the present disclosure, a method includes receiving a layout; performing an optimization process to the layout to generate an optimized layout, wherein the optimization process comprising simulating a mask image of a photomask based on the layout; simulating an aerial image projected on a photoresist layer based on the mask image; simulating a resist image of the photoresist layer based on the aerial image; simulating an etch image of a layer underneath the photoresist layer based on the resist image; and performing an inverse lithographic technology (ILT) process to generate the optimized layout, wherein the ILT process is performed based on the mask image, the aerial image, the resist image, and the etch image; and fabricating a photomask based on the optimized layout.

In some embodiments, wherein the ILT process comprises performing an iterative process to the layout using a function defined as:

$${{w}^{1} ← {w}^{0} - η \frac{dL}{dw} \vert}_{w = {w}^{0}} \\ {w}^{*} = arg min L ( w )$$

wherein w is a variable of the layout;
w⁰, w¹, and w* are layouts at different stages of the iterative process;
η is a learning rate; and
L(w) is a loss function, and L(w) is defined as a difference between the simulated etch image and the layout.

In some embodiments, wherein the function is further expressed as:

$${{w}^{1} ← {w}^{0} - η \frac{dL}{dEI} * \frac{dEI}{dRI} * \frac{dRI}{dAI} * \frac{dAI}{dMI} * \frac{dMI}{dw} \vert}_{EI = {EI}^{0} , RI = {RI}^{0} , AI = {AI}^{0} , MI = {MI}^{0} , w = {w}^{0}} \\ {w}^{*} = arg min L ( w )$$

wherein EI is the simulated etch image;
RI is the simulated resist image;
AI is the simulated aerial image; and
MI is the simulated mask image.

In some embodiments, wherein a pattern of the layout comprising a first feature; a pattern of the photomask comprising a second feature and a first assisting feature, wherein the second feature corresponds to the first feature of the pattern of the layout, while the pattern of the layout has no feature corresponding to the first assisting feature.

In some embodiments, the method further includes patterning the photoresist layer using the photomask, such that the pattern of the photomask is transferred to the photoresist layer, wherein a pattern of the photoresist layer comprises a third feature and a second assisting feature, wherein the third feature corresponds to the second feature of the pattern of the photomask, and the second assisting feature corresponds to the first assisting feature of the pattern of the photomask.

In some embodiments, the method further includes patterning a layer using the photoresist layer, such that the pattern of the photoresist layer is transferred to the layer, wherein a pattern of the layer comprises a fourth feature, wherein the fourth feature corresponds to the third feature of the pattern of the photoresist layer, while the pattern of the layer has no feature corresponding to the second assisting feature of the pattern of the photoresist layer.

In some embodiments, simulating the resist image of the photoresist layer is performed using a machine-learning based module, and the machine-learning based module is trained based on a database of aerial image data and resist image data.

In some embodiments, simulating the etch image of the layer is performed using a machine-learning based module, and the machine-learning based module is trained based on a database of resist image data and etch image data.

In some embodiments of the present disclosure, a method includes receiving a layout; performing a first optimization process to the layout to generate a first optimized layout; transferring the first optimized layout from a real valued image to a level-set image; performing a second optimization process to the first optimized layout with the level-set image to generate a second optimized layout; and fabricating a photomask based on the second optimized layout.

In some embodiments, the first and second optimization processes both comprise performing an inverse lithographic technology (ILT) process.

In some embodiments, the first optimization process comprises simulating a mask image of the photomask based on the layout; simulating an aerial image projected on a photoresist layer based on the mask image; simulating a resist image of the photoresist layer based on the aerial image; simulating an etch image of a layer underneath the photoresist layer based on the resist image; and performing an inverse lithographic technology (ILT) process to generate the optimized layout, wherein the ILT process is performed based on the mask image, the aerial image, the resist image, and the etch image.

In some embodiments, wherein the ILT process comprises performing an iterative process to the layout using a function defined as:

$${{w}^{1} ← {w}^{0} - η \frac{dL}{dEI} * \frac{dEI}{dRI} * \frac{dRI}{dAI} * \frac{dAI}{dMI} * \frac{dMI}{dw} \vert}_{EI = {EI}^{0} , RI = {RI}^{0} , AI = {AI}^{0} , MI = {MI}^{0} , w = {w}^{0}} \\ {w}^{*} = arg min L ( w )$$

wherein w is a variable of the layout;
w⁰, w¹, and w* are layouts at different stages of the iterative process;
η is a learning rate;
L(w) is a loss function, and L(w) is defined as a difference between the simulated etch image and the layout;
EI is the simulated etch image;
RI is the simulated resist image;
AI is the simulated aerial image; and
MI is the simulated mask image.

In some embodiments, a pattern of the layout comprises a first feature; and a pattern of the photomask comprises a second feature and a first assisting feature, wherein the second feature corresponds to the first feature of the pattern of the layout, while the pattern of the layout has no feature corresponding to the first assisting feature.

In some embodiments, the method further includes patterning a layer using the photomask, such that the pattern of the photomask is transferred to the layer, wherein a pattern of the layer comprises a third feature, wherein the third feature corresponds to the second feature of the pattern of the photomask, while the pattern of the layer has no feature corresponding to the first assisting feature of the pattern of the photomask.

In some embodiments of the present disclosure, a method includes receiving a layout, a pattern of the layout comprising a first feature; performing an optimization process to the layout to generate an optimized layout; fabricating a photomask based on the optimized layout, a pattern of the photomask comprising a second feature and a first assisting feature, wherein the second feature corresponds to the first feature of the pattern of the layout, while the pattern of the layout has no feature corresponding to the first assisting feature; and patterning a layer using the photomask, such that the pattern of the photomask is transferred to the layer, wherein a pattern of the layer comprises a third feature, wherein the third feature corresponds to the second feature of the pattern of the photomask, while the pattern of the layer has no feature corresponding to the first assisting feature of the of the pattern of the photomask.

In some embodiments, the method further includes patterning a photoresist layer using the photomask, such that the pattern of the photomask is transferred to the photoresist layer, wherein a pattern of the photoresist layer comprises a fourth feature and a second assisting feature, wherein the fourth feature corresponds to the second feature of the pattern of the photomask, and the second assisting feature corresponds to the first assisting feature of the pattern of the photomask, wherein the patterning the layer comprises etching the layer through the photoresist layer.

In some embodiments, the first assisting feature is adjacent to a corner of the second feature.

In some embodiments, the optimization process comprises an inverse lithographic technology (ILT) process.

In some embodiments, performing the optimization process comprises simulating a mask image of the photomask based on the layout; simulating an aerial image projected on a photoresist layer based on the mask image; simulating a resist image of the photoresist layer based on the aerial image; and simulating an etch image of the layer based on the resist image, wherein the optimized layout is determined based on the mask image, the aerial image, the resist image, and the etch image.

In some embodiments, simulating the resist image of the photoresist layer and simulating the etch image of the layer are performed using machine-learning based modules.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a layout;
performing an optimization process to the layout to generate an optimized layout, wherein the optimization process comprising:
simulating a mask image of a photomask based on the layout;
simulating an aerial image projected on a photoresist layer based on the mask image;
simulating a resist image of the photoresist layer based on the aerial image;
simulating an etch image of a layer underneath the photoresist layer based on the resist image; and
performing an inverse lithographic technology (ILT) process to generate the optimized layout, wherein the ILT process is performed based on the mask image, the aerial image, the resist image, and the etch image; and
fabricating a photomask based on the optimized layout.

2. The method of claim 1, wherein the ILT process comprises performing an iterative process to the layout using a function defined as:
$${{w}^{1} ← {w}^{0} - η \frac{dL}{dw} \vert}_{w = {w}^{0}} \\ {w}^{*} = arg min L ( w )$$
wherein w is a variable of the layout;
w⁰, w¹, and w* are layouts at different stages of the iterative process;
η is a learning rate; and
L(w) is a loss function, and L(w) is defined as a difference between the simulated etch image and the layout.

3. The method of claim 2, wherein the function is further expressed as:
$${{w}^{1} ← {w}^{0} - η \frac{dL}{dEI} * \frac{dEI}{dRI} * \frac{dRI}{dAI} * \frac{dAI}{dMI} * \frac{dMI}{dw} \vert}_{EI = {EI}^{0} , RI = {RI}^{0} , AI = {AI}^{0} , MI = {MI}^{0} , w = {w}^{0}} \\ {w}^{*} = arg min L ( w )$$
wherein EI is the simulated etch image;
RI is the simulated resist image;
AI is the simulated aerial image; and
MI is the simulated mask image.

4. The method of claim 1, wherein:
a pattern of the layout comprising a first feature;
a pattern of the photomask comprising a second feature and a first assisting feature, wherein the second feature corresponds to the first feature of the pattern of the layout, while the pattern of the layout has no feature corresponding to the first assisting feature.

5. The method of claim 4, further comprising patterning the photoresist layer using the photomask, such that the pattern of the photomask is transferred to the photoresist layer, wherein a pattern of the photoresist layer comprises a third feature and a second assisting feature, wherein the third feature corresponds to the second feature of the pattern of the photomask, and the second assisting feature corresponds to the first assisting feature of the pattern of the photomask.

6. The method of claim 5, further comprising patterning a layer using the photoresist layer, such that the pattern of the photoresist layer is transferred to the layer, wherein a pattern of the layer comprises a fourth feature, wherein the fourth feature corresponds to the third feature of the pattern of the photoresist layer, while the pattern of the layer has no feature corresponding to the second assisting feature of the pattern of the photoresist layer.

7. The method of claim 1, wherein simulating the resist image of the photoresist layer is performed using a machine-learning based module, and the machine-learning based module is trained based on a database of aerial image data and resist image data.

8. The method of claim 1, wherein simulating the etch image of the layer is performed using a machine-learning based module, and the machine-learning based module is trained based on a database of resist image data and etch image data.

9. A method, comprising:
receiving a layout;
performing a first optimization process to the layout to generate a first optimized layout;
transferring the first optimized layout from a real valued image to a level-set image;
performing a second optimization process to the first optimized layout with the level-set image to generate a second optimized layout; and
fabricating a photomask based on the second optimized layout.

10. The method of claim 9, wherein the first and second optimization processes both comprise performing an inverse lithographic technology (ILT) process.

11. The method of claim 9, wherein the first optimization process comprising:
simulating a mask image of the photomask based on the layout;
simulating an aerial image projected on a photoresist layer based on the mask image;
simulating a resist image of the photoresist layer based on the aerial image;
simulating an etch image of a layer underneath the photoresist layer based on the resist image; and
performing an inverse lithographic technology (ILT) process to generate the optimized layout, wherein the ILT process is performed based on the mask image, the aerial image, the resist image, and the etch image.

12. The method of claim 11, wherein the ILT process comprises performing an iterative process to the layout using a function defined as:
$${{w}^{1} ← {w}^{0} - η \frac{dL}{dEI} * \frac{dEI}{dRI} * \frac{dRI}{dAI} * \frac{dAI}{dMI} * \frac{dMI}{dw} \vert}_{EI = {EI}^{0} , RI = {RI}^{0} , AI = {AI}^{0} , MI = {MI}^{0} , w = {w}^{0}} \\ {w}^{*} = arg min L ( w )$$
wherein w is a variable of the layout;
w⁰, w¹, and w* are layouts at different stages of the iterative process;
η is a learning rate;
L(w) is a loss function, and L(w) is defined as a difference between the simulated etch image and the layout;
EI is the simulated etch image;
RI is the simulated resist image;
AI is the simulated aerial image; and
MI is the simulated mask image.

13. The method of claim 9, wherein:
a pattern of the layout comprises a first feature; and
a pattern of the photomask comprises a second feature and a first assisting feature, wherein the second feature corresponds to the first feature of the pattern of the layout, while the pattern of the layout has no feature corresponding to the first assisting feature.

14. The method of claim 13, further comprising patterning a layer using the photomask, such that the pattern of the photomask is transferred to the layer, wherein a pattern of the layer comprises a third feature, wherein the third feature corresponds to the second feature of the pattern of the photomask, while the pattern of the layer has no feature corresponding to the first assisting feature of the pattern of the photomask.

15. A method, comprising:
receiving a layout, a pattern of the layout comprising a first feature;
performing an optimization process to the layout to generate an optimized layout;
fabricating a photomask based on the optimized layout, a pattern of the photomask comprising a second feature and a first assisting feature, wherein the second feature corresponds to the first feature of the pattern of the layout, while the pattern of the layout has no feature corresponding to the first assisting feature; and
patterning a layer using the photomask, such that the pattern of the photomask is transferred to the layer, wherein a pattern of the layer comprises a third feature, wherein the third feature corresponds to the second feature of the pattern of the photomask, while the pattern of the layer has no feature corresponding to the first assisting feature of the of the pattern of the photomask.

16. The method of claim 15, further comprising:
patterning a photoresist layer using the photomask, such that the pattern of the photomask is transferred to the photoresist layer, wherein a pattern of the photoresist layer comprises a fourth feature and a second assisting feature, wherein the fourth feature corresponds to the second feature of the pattern of the photomask, and the second assisting feature corresponds to the first assisting feature of the pattern of the photomask, wherein the patterning the layer comprises etching the layer through the photoresist layer.

17. The method of claim 15, wherein the first assisting feature is adjacent to a corner of the second feature.

18. The method of claim 15, wherein the optimization process comprises an inverse lithographic technology (ILT) process.

19. The method of claim 15, wherein performing the optimization process comprises:
simulating a mask image of the photomask based on the layout;
simulating an aerial image projected on a photoresist layer based on the mask image;
simulating a resist image of the photoresist layer based on the aerial image; and
simulating an etch image of the layer based on the resist image, wherein the optimized layout is determined based on the mask image, the aerial image, the resist image, and the etch image.

20. The method of claim 19, wherein simulating the resist image of the photoresist layer and simulating the etch image of the layer are performed using machine-learning based modules.
